(19) United States
(12) Patent Application Publication
(10) Pub. No.: US 2017/0092649 A1
(43) Pub. Date: Mar. 30, 2017

(54) SEMICONDUCTOR DEVICE AND METHOD FOR MANUFACTURING THE SAME

(71) Applicant: RENESAS ELECTRONICS CORPORATION, Tokyo (JP)

(72) Inventor: Hiromichi TAKAOKA, Ibaraki (JP)

(21) Appl. No.: 15/270,132

(22) Filed: Sep. 20, 2016

(30) Foreign Application Priority Data
Sep. 30, 2015 (JP) 2015-194130

(51) Int. Cl. H01L 27/11; H01L 23/535; H01L 21/311; H01L 49/02

(52) U.S. Cl. CPC H01L 27/1104; H01L 28/60; H01L 23/535; H01L 21/31116

(57) ABSTRACT

To improve reliability of SRAM. In a memory cell of the SRAM, a coupling capacitance is provided between memory nodes in consideration of dynamic stability.

### CLAIM OF PRIORITY

The present application claims priority from Japanese Patent application serial no. 2015-194130, filed on Sep. 30, 2015, the content of which is hereby incorporated by reference into this application.

### BACKGROUND OF THE INVENTION

Field of the Invention

The present invention relates to a semiconductor device and its manufacturing method, and in particular, to an effective technology when being applied to a semiconductor device having built-in SRAM.

Description of the Related Art

Since the SRAM (Static Random Access Memory) generally operates at high speed compared with DRAM (Dynamic Random Access Memory) and can be manufactured by a process for a logic LSI (Large Scale integration), it is used as cache memory that is mounted mixedly with the logic LSI. For example, the SRAM is mounted on a system LSI together with a CPU (Central Processing Unit) and the logic LSI. Moreover, in a DRAM-mixed-mounted product (eDRAM: Embedded Dynamic Random Access Memory), the SRAM is used as cache memory between the CPU and the DRAM.

With miniaturization of the SRAM, it is becoming difficult to develop an SRAM cell capable of performing stable operation. By the miniaturization, deterioration of a dynamic noise margin (DNM) and a static noise margin (SNM) that are indices showing stability of a read operation and stability of data retention of a memory cell becomes a problem.

As a background art of this technical field, there is a technology like Patent Document 1. Patent Document 1 discloses a “technology related to improvement of performance of a semiconductor integrated circuit device such that an inter-storage node capacitance of SRAM and an element having an analog capacitance are formed on a single substrate.”

Moreover, Patent Document 2 discloses a “technology of taking a countermeasure against a soft error by providing an MIM node capacitor in an SRAM memory cell.”

Patent Document 3 discloses a “technology of further increasing stability of a memory cell in consideration of dynamic stability of an SRAM cell.”

Patent Document 4 discloses a “semiconductor memory device that is excellent in productivity by evaluation of an operation margin using DNM.”

### Patent Document

[Patent Document 1] Japanese Patent Application Laid-Open No. 2003-7978

[Patent Document 2] Japanese Patent Application Laid-Open No. 2006-19371

[Patent Document 3] Japanese Patent Application Laid-Open No. 2008-135461

[Patent Document 4] Japanese Patent Application Laid-Open No. 2010-198711

As described above, in the design of the SRAM, it is an important issue to establish both reduction in cell size and stability of operations and data retention performance of a memory cell.

The above-mentioned Patent Document 1 has a soft error countermeasure of alpha rays as a main object, and does not include a description about improvement of a SNM and a DNM.

Moreover, with a configuration where a capacitance to be added to a node is connected between a substrate and a power supply like the above-mentioned Patent Document 2, it is necessary to connect a counter electrode to the substrate or the power supply in each MIM. Therefore, two connection sites are needed to one memory cell, which results in increase in the area. Moreover, with such a capacitance formed between the substrate or the power supply, a DNM improvement effect is small.

With a configuration of the above-mentioned Patent Document 3, since a capacitance of the MIMs that are serially connected becomes Cn×Cn/(Cn+Cn), the capacitance becomes one-half of the capacitance Cn of one MIM, and accordingly, the capacitance will decrease.

In the above-mentioned Patent Document 4, since a transistor part and a capacitance part are treated as one body, when it is used in the DRAM-mixed-mounted product (eDRAM), for example, it is not efficient to mount an MIM of the eDRAM thereon.

As described above, when it is intended to secure stability of an SRAM cell operation by the conventional technique, it is difficult to acquire sufficient stability because of expansion of an occupied area of the memory cell, which becomes hindrance of high integration, and other reasons.

Other problems and new features will become clear from description and the accompanying drawings of this specification.

### SUMMARY OF THE INVENTION

According to one embodiment, in the memory cell of the SRAM, a coupling capacitance is provided between memory nodes in consideration of dynamic stability.

According to the one embodiment, reliability of the SRAM improves.

### BRIEF DESCRIPTION OF THE DRAWINGS

FIG. 1 is a schematic representation of an SRAM configuration according to one embodiment of the present invention;

FIG. 2 is an SRAM cell circuit diagram according to the one embodiment of the present invention;

FIG. 3 is a timing chart of an SRAM according to the one embodiment of the present invention;

FIG. 4 is a 2×2 cell array layout diagram of an SRAM cell according to the one embodiment of the present invention (first embodiment);

FIG. 5 is a diagram showing a section A-A′ of FIG. 4;

FIG. 6A is a circuit diagram of a common six-transistor-type SRAM cell;

FIG. 6B is the SRAM cell circuit diagram showing a node capacitance arrangement according to the one embodiment of the present invention;

FIG. 6C is the SRAM cell circuit diagram showing a node capacitance arrangement of an examination example;

FIG. 6D is the SRAM cell circuit diagram showing the node capacitance arrangement of the examination example;

FIG. 7 is a diagram showing a read operation waveform of the SRAM cell according to the one embodiment of the present invention;

FIG. 8 is a diagram showing word-line access time dependence of a noise margin of the SRAM cell according to the one embodiment of the present invention;

FIG. 9 is the 2×2 cell array layout diagram of the SRAM cell according to the one embodiment of the present invention (second embodiment);

FIG. 10A is a hierarchy conceptual diagram of the SRAM cell array layout of FIG. 9;

FIG. 10B is a modification of FIG. 10A;

FIG. 11 is a diagram showing the section A-A′ of FIG. 9;

FIG. 12 is a sectional view of a DRAM-mixed-mounted structure according to the one embodiment of the present invention;

FIG. 13 is a diagram showing a section B-B′ of FIG. 9;

FIG. 14A is a sectional view showing a part of a manufacturing process of a semiconductor device according to the one embodiment of the present invention;

FIG. 14B is a sectional view showing a part of the manufacturing process of the semiconductor device according to the one embodiment of the present invention;

FIG. 14C is a sectional view showing a part of the manufacturing process of the semiconductor device according to the one embodiment of the present invention;

FIG. 14D is a sectional view showing a part of the manufacturing process of the semiconductor device according to the one embodiment of the present invention;

FIG. 14E is a sectional view showing a part of the manufacturing process of the semiconductor device according to the one embodiment of the present invention;

FIG. 14F is a sectional view showing a part of the manufacturing process of the semiconductor device according to the one embodiment of the present invention;

FIG. 14G is a sectional view showing a part of the manufacturing process of the semiconductor device according to the one embodiment of the present invention;

FIG. 15 is a sectional view of the DRAM-mixed-mounted structure according to the one embodiment of the present invention (third embodiment); and

FIG. 16 is a sectional view of the DRAM-mixed-mounted structure according to the one embodiment of the present invention (modification of third embodiment).

### DETAILED DESCRIPTION OF THE PREFERRED EMBODIMENTS

Hereinafter, embodiments are described using drawings. Incidentally, in each drawing, the same symbol is given to the same constitutional component and its detailed explanation is omitted for an overlapping part.

### First Embodiment

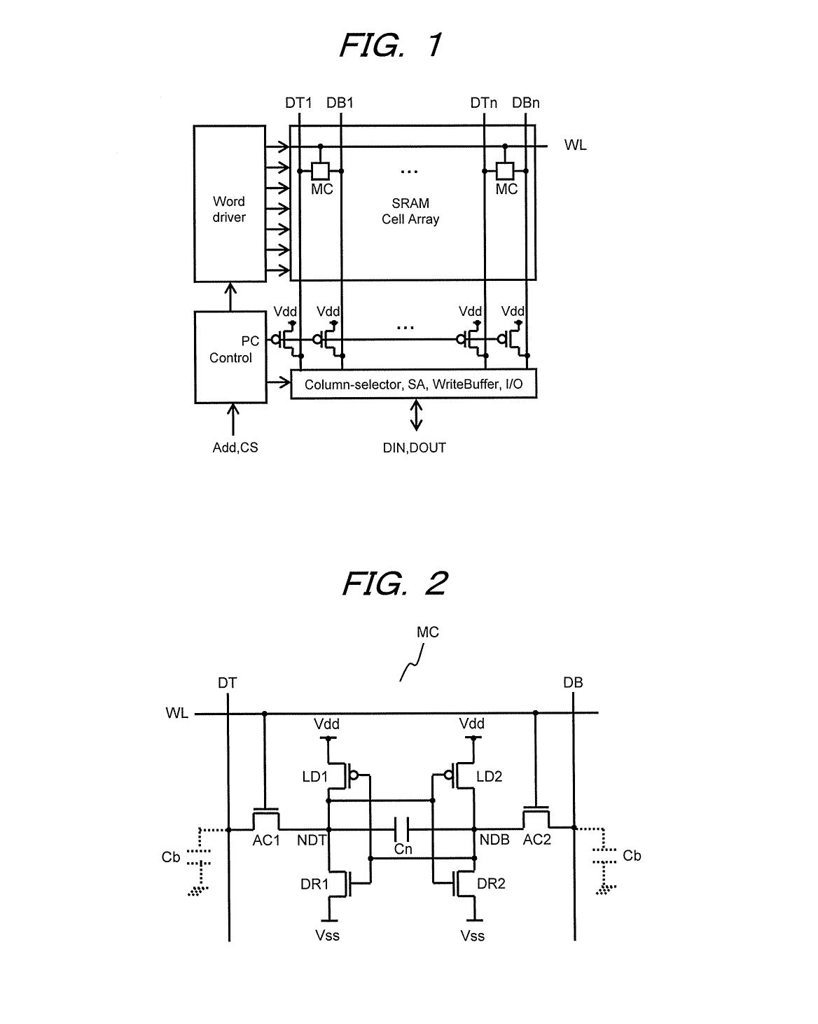

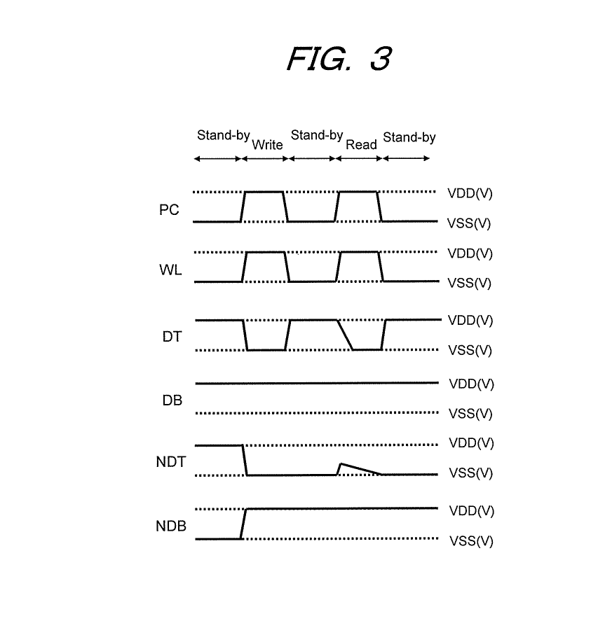

SRAM and its memory cell in a first embodiment are explained using FIG. 1 to FIG. 3. FIG. 1 is a diagram showing an overall configuration of the SRAM. FIG. 2 shows a memory cell MC in FIG. 1. The multiple memory cells MC shown in FIG. 2 are aligned in the SRAM of FIG. 1 as an SRAM cell array. FIG. 3 is a timing chart at the time of write/read/stand-by operations of the SRAM comprised of FIG. 1. Incidentally, a point to which attention should be paid in FIG. 3 is that bit line precharge of a non-selected bit in addition to a selected bit should be turned OFF.

Referring to FIG. 1, the SRAM of this embodiment has almost the same configuration except for a configuration of the memory cell MC as that of common SRAM. The memory cell MC is disposed between a pair of bit lines (digit lines) DT, DB, and is electrically connected to the bit lines DT, DB, respectively. The bit line DT is Digit Line True, and the bit line DB is Digit Line Bar. Moreover, the memory cell MC is also electrically connected to a word line WL. An address of a target memory cell MC is assigned by a column selector and a word driver, and writing and reading of data to/from the selected memory cell MC are performed. From the bit lines DT1, DB1 to bit lines DTn, DBn, multiple (n pieces of) memory cells MC are arranged contiguously in an array form.

The memory cell MC of the SRAM is configured with a latch comprised of two inverters that include driver transistors DR1, DR2 and load transistors LD1, LD2 and two access transistors AC1, AC2, as shown in FIG. 2. The latch has two terminals (nodes NDT, NDB), and can retain information of 0 or 1 regularly by taking two stable states of High/Low or Low/High complementarily, respectively. Incidentally, a node NDT is connected to the bit line DT, and a node NDB is connected to the bit line DB.

Here, in an SRAM memory cell of this embodiment, as is shown in FIG. 2, a node capacitance Cn is provided between two terminals of the latch, i.e., the node NDT and the node NDB. Thereby, since a capacitance value of the memory node increases, stability (dynamic noise margin) of an SRAM cell improves.

An operation of the SRAM is briefly explained using FIG. 3. A memory terminal (node NDT) of the SRAM is set to High and a memory terminal (node NDB) is set to Low. The writing of data in a case where the memory terminal (node NDT) is set to Low and the memory terminal (node NDB) is set to High is explained. The bit line DT connected to the memory terminal (node NDT) that is desired to be Low is set to ‘L,’ the memory terminal (node NDB) that is desired to be High is set to ‘H,’ and the word line WL is set to ‘H’ from ‘L.’ By maintaining this state for a fixed period, the memory terminal (node NDT) changes to Low, and the memory terminal (node NDB) changes to High, and accordingly, the writing is performed.

Meanwhile in reading data, the bit lines DT, DB are precharged to a power supply voltage and after this the word line WL is changed to the high level (‘H’) from the low level (‘L’). Although the bit line DB connected to the memory terminal (node NDB) that is High does not change, a potential of the bit line DT connected to the memory terminal (node NDT) that is Low decreases. Data can be read by amplifying a potential difference of this bit line with a sense amplifier (SA) etc.

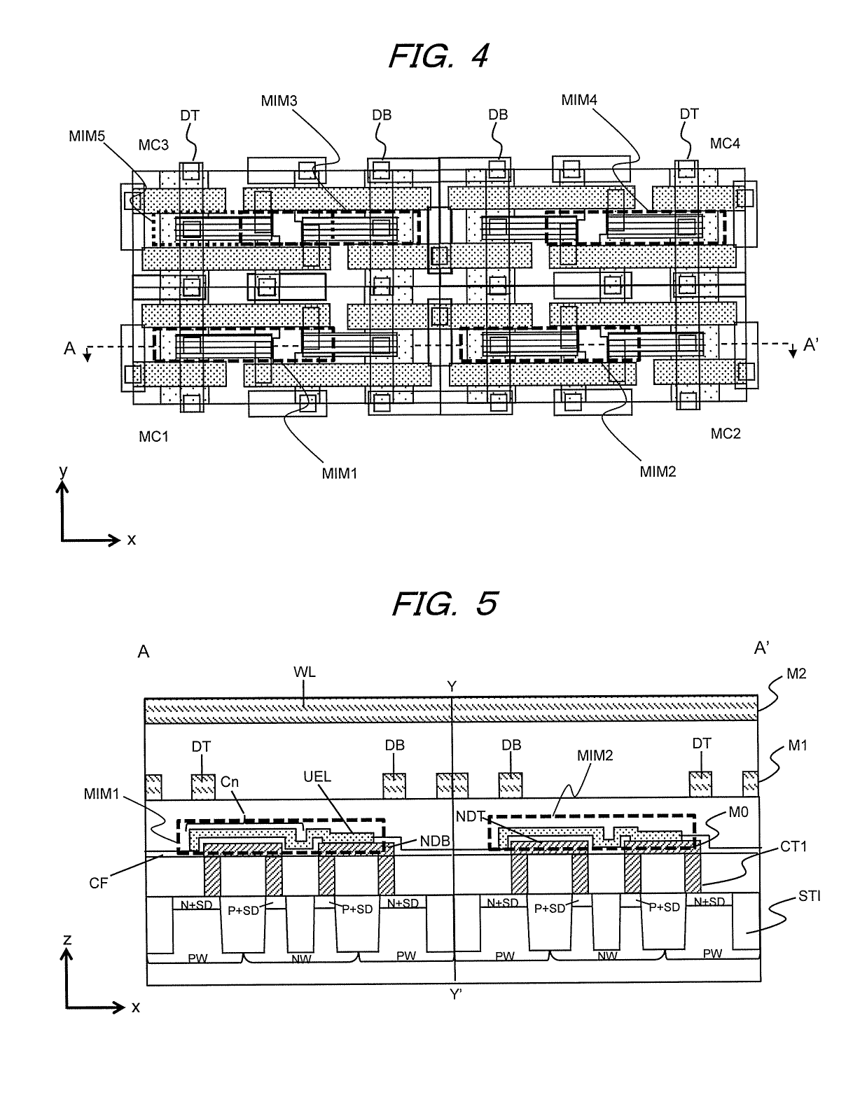

A layout and its cross-sectional structure of the SRAM cell of this embodiment are explained using FIG. 4 and FIG. 5. FIG. 4 is an example in which the capacitance Cn is formed between memory nodes as shown by FIG. 2, and the example has a 2×2 layout in which four memory cells MC1 to MC4 are disposed with two rows in both longitudinal and transverse directions. Moreover, FIG. 5 shows a section A-A′ in FIG. 4.

As shown in FIG. 4, in the layout of the SRAM cell of this embodiment, MIM (Metal Insulator Metal) capacitances MIM1 to MIM4 each of which has a capacitance Cn in each of the memory cells MC1 to MC4 are provided. Incidentally, as shown in FIG. 4, the MIM capacitances provided in the memory cells MC disposed between the same bit lines DT, DB are laid out in a staggered form so that the MIM capacitances may not arranged shifted to either of the bit line DT side or DB side. That is, while the MIM1 provided in the memory cell MC1 is disposed to be closer to the bit line DT side than to the middle of the bit line DT and the bit line DB, the MIM3 provided in the memory cell MC3 is disposed to be closer to the bit line DB side than to the middle of the bit line DT and the bit line DB. Similarly, while the MIM2 provided in the memory cell MC2 is disposed to be closer to the bit line DB side than to the middle of the bit line DB and the bit line DT, the MIM4 provided in the memory cell MC4 is disposed to be closer to the bit line DT side than to the middle of the bit line DB and the bit line DT.

For example, if the MIM capacitance provided in the memory cell MC3 is disposed to be closer to the left side of FIG. 4 that is the same side as that of the MIM1 of the memory cell MC1, i.e., to the bit line DT side, the MIM capacitances will have a configuration where they are shifted to the bit line DT side, and peripheral environments of the bit line DT and of the bit line DB will become different from each other. As a result, there is concern about a problem that capacitances of the bit line DT and of the bit line DB differ, which makes correct sensing impossible. Then, as shown in FIG. 4, the MIM capacitances to be provided in the memory cells MC disposed between the same bit lines DT, DB are arranged so that the arrangement may become symmetrical. Similarly, regarding the MIM capacitances provided in the memory cell MC2 and the memory cell MC4, the MIM2 of the memory cell MC2 is disposed to be closer to the bit line DB side and the MIM4 of the memory cell MC4 is disposed to be closer to the bit line DT side.

Moreover, in FIG. 4, the memory cells MC1 and MC2 that are adjacent to each other are connected to the same word line WL, and the memory cells MC3 and MC4 that are adjacent to each other are connected to the same word line WL, similarly. For example, when the MIM capacitance provided in the memory cell MC1 is disposed to be closer to the bit line DT side, it is preferable that the MIM capacitance MIM2 of the memory cell MC2 connected to the same word line WL is disposed to be closer to the bit line DB side similarly with disposition of the MIM capacitance MIM1. Similarly, when the MIM3 provided in the memory cell MC3 is disposed to be closer to the bit line DB side, it is preferable that the MIM capacitance MIM4 of the memory cell MC4 connected to the same word line WL is disposed to be closer to the bit line DT side similarly with disposition of the MIM capacitance MIM3 in the memory cell MC3.

That is, in the memory cell array, it is preferable that the MIM capacitance of the SRAM cell connected to a certain word line WL is disposed to be closer to the same side to which a MIM capacitance of another SRAM cell connected to the same (common) word line WL is disposed.

The MIM capacitance provided in each memory cell MC is formed with a cross-sectional structure shown in FIG. 5. An upper electrode UEL is formed by a capacitance insulation film CF being formed on the nodes NDT, NDB, a part of the capacitance insulation film CF on the node NDB being removed by etching, and a formed conductive film being processed. The node capacitance Cn is formed as a single element with this electrode UEL and the node NDT that serves as a lower electrode LEL.

Incidentally, in FIG. 4, regarding an arrangement of the MIM1 and the MIM3, they may be arranged so that the MIM1 may overlap the bit line DT planarly and the MIM3 may overlap the bit line DB planarly. Similarly, regarding an arrangement of the MIM2 and the MIM4, they may be arranged so that the MIM2 may overlap the bit line DB planarly and the MIM4 may overlap the bit line DT planarly. Regarding the overlapping of the MIM and the bit line, the MIM and the bit line can be disposed so as to overlap each other planarly by forming at least one of the upper electrode UEL, the capacitance insulation film CF, and the lower electrode LEL that constitute the MIM so that it may overlap the bit line planarly.

Moreover, regarding disposition of the MIM1 and the MIM3, the MIM1 may be disposed apart from the bit line at a fixed interval and the MIM3 may be disposed from the bit line DT at a fixed interval. Similarly, regarding disposition of the MIM2 and the MIM4, the MIM2 may be disposed apart from the bit line DT at a fixed interval, and the MIM4 may be disposed apart from the bit line DB at a fixed interval.

Moreover, although the bit line DT and the bit line DB constitute a pair of bit lines in the memory cell array; regarding the MIMs provided between this bit line pair, it is desirable that the number of the MIMs disposed to be closer to the bit line DT side and the number of the MIMs disposed to be closer to the bit line DB side are the same number. This is to keep peripheral environments of the bit line DT and of the bit line DB not different from each other, as described above.

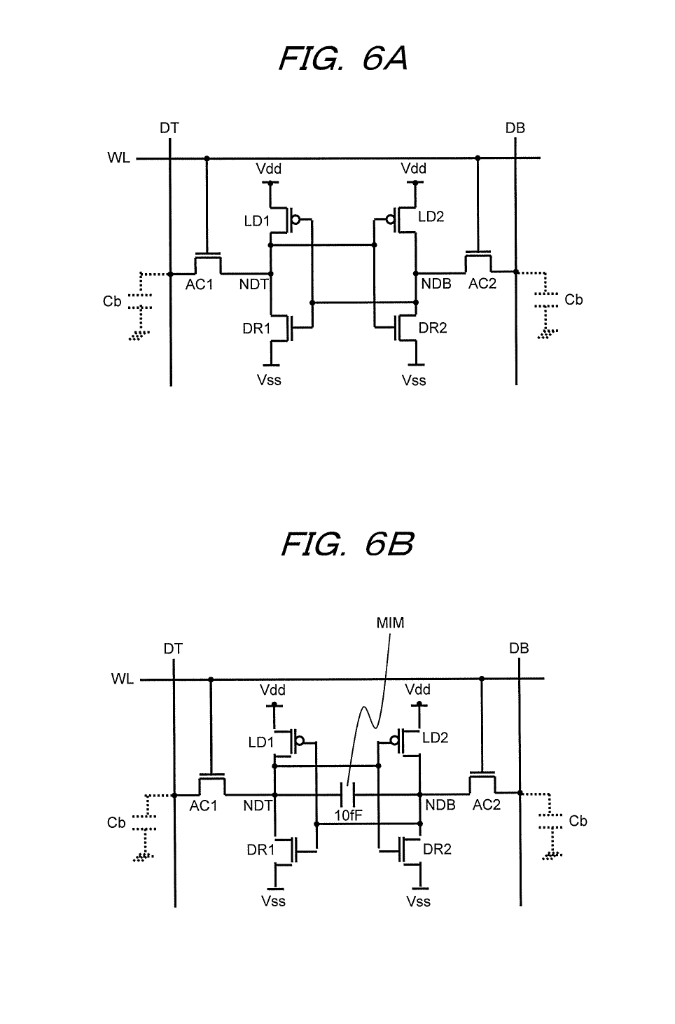

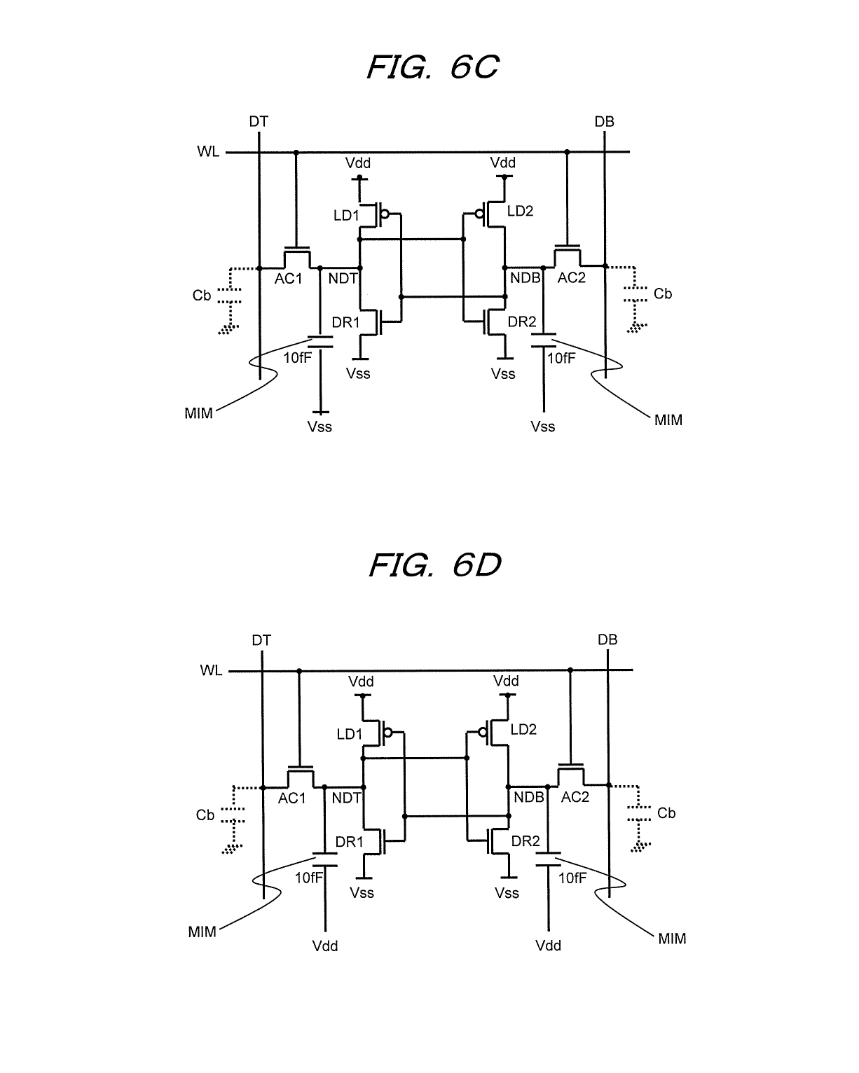

Next, a modification of this embodiment is explained using FIG. 6A to FIG. 6D. FIG. 6A is a common six-transistor-type SRAM cell shown for comparison. Moreover, FIG. 6B is a circuit diagram in which the MIM capacitance of 10 fF is provided between the nodes NDT and NDB, showing the SRAM memory cell structure of this embodiment explained above. FIG. 6C is a diagram in which the MIM capacitances of 10 fF to Vss are provided in the nodes NDT, NDB, respectively, and FIG. 6D is a diagram in which the MIM capacitances of 10 fF to Vdd are provided in the nodes NDT, NDB, respectively.

As shown in FIG. 6B, by providing the node capacitance Cn of, for example, about 10 fF between two terminals of the latch, i.e., the node NDT and the node NDB, the capacitance value of the memory node increases and the stability (dynamic noise margin) of the SRAM cell improves. As a method for increasing the capacitance value of the memory node, it is considerable that capacitances to Vss or to Vdd are added to both of the node NDT and the node NDB, as shown in FIG. 6C and FIG. 6D. These memory node capacitances are formed with the MIMs, as shown in FIG. 5.

By providing node capacitances in respective memory nodes individually as shown in FIG. 6C and FIG. 6D, it is possible to increase the capacitance value of the memory node and to improve the stability (dynamic noise margin) of the SRAM memory cell, like FIG. 6B. However, since it is necessary to form the MIM for every node, there is a concern over occurrence of restrictions in the cell layout or enlargement of an area occupied by the memory cell. Incidentally, although FIG. 6B to FIG. 6D show the example where the MIM capacitance of 10 fF is added, respectively, the capacitance value 10 fF of the node capacitance Cn that was added is merely an illustration, and is not limited to this.

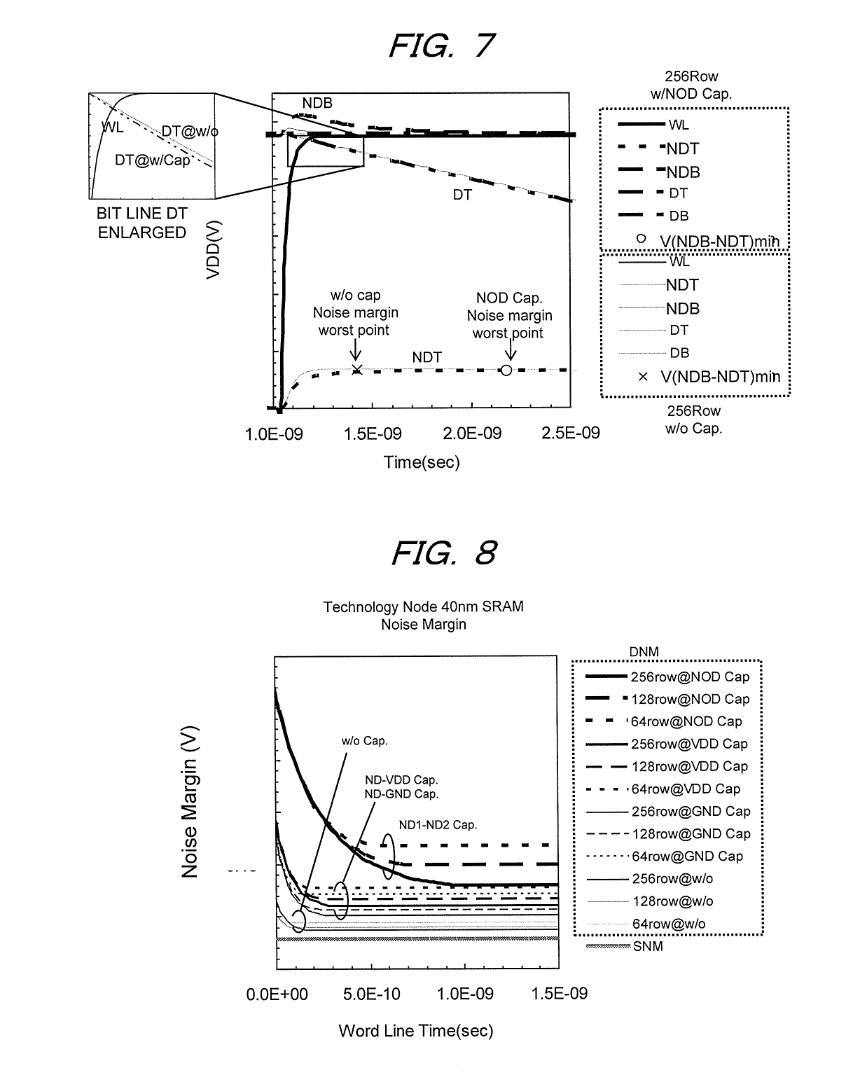

Next, an effect when the node capacitance Cn is provided between the node NDT and the node NDB is explained using FIG. 7 and FIG. 8. FIG. 7 shows a waveform comparison at the time of read operations in the SRAM memory cells of FIG. 6A and FIG. 6B. W/NOD Cap. shows a waveform at the time of adding a coupling capacitance of 10 fF between the node NDT and the node NDB (FIG. 6B). On the other hand, w/o Cap. shows a waveform of the common six-transistor-type SRAM cell (FIG. 6A) to which no coupling capacitance is added.

In the case of W/NOD Cap., i.e., where the node capacitance Cn is provided between the memory nodes, when the word line opens, the node NDT becomes floating and the node NDB also becomes floating because of coupling. Since the node NDB becomes floating, a potential difference between the NDT and the NDB is maintained, and a data retention margin is enlarged. Moreover, the present inventors have found that even when the node NDB is floated, since Vgs of the DR1 becomes large, a potential of bit line difference tends to become somewhat larger, and have clarified that an effect of a further enhanced data retention characteristic can be acquired.

FIG. 8 is a diagram showing word-line access time dependence of the noise margin. In FIG. 6A to FIG. 6D, the number of Rows is changed to 64, 128, and 256, and the word-line time dependence of the noise margin is shown. The node capacitance provided between the memory nodes is set to a fixed value of 10 fF. A SNM (static noise margin) of FIG. 8 is a noise margin of a non-selection precharge operation. The shorter the word-line access time and the smaller the Row number (bit line capacitance), the more the DNM (dynamic noise margin) is improved.

The present inventors have made it clear that providing the capacitance between the memory nodes as a coupling capacitance has a larger amount of improvement in noise margin than adding a capacitance to Vdd and to GND assuming that the node capacitance is constant. Compared with a case where a capacitance is formed between the node and Vss or Vdd, a larger effect can be acquired.

Incidentally, in this embodiment, although the semiconductor device is explained using the example of the single-port SRAM of the six-transistor type, the same effect can be acquired also with dual-port SRAM by the same technique.

Moreover, although for the capacitive element, the MIM is used as one example, the capacitive element is not limited to the MIM as long as it is a capacitive element disposed between the MOS transistor and the metal wiring M1 of the first layer. For example, the same effect can be acquired even if a parasitic capacitance of a TFT is made to become parasitic as the coupling capacitance.

According to the configuration of this embodiment, since the capacitance value of the memory node ND increases, the stability (dynamic noise margin) of the SRAM memory cell improves. By connecting a single MIM capacitance between the node NDT and the node NDB, the MIM capacitance can further be increased as compared with a conventional example where two MIM capacitances are serially connected.

Moreover, since the capacitance value of the memory node ND increases, a tolerance of a bit line capacitance Cb allowed for one bit line becomes large, and design flexibility of a word/bit configuration improves.

Moreover, since the memory node ND having stored High data floats by the coupling capacitance Cn at the time of the read operation and an overdrive is applied to Vgs of the driver transistor, a cell current increases temporarily and the peak cell rate Cb·Vb/Iread characteristics improves.

Furthermore, as a secondary effect, soft error resistance increases by increase of the capacitance value of the memory node ND, and it becomes possible to retain data stably. The reliability of the SRAM improves by these effects.

### Second Embodiment

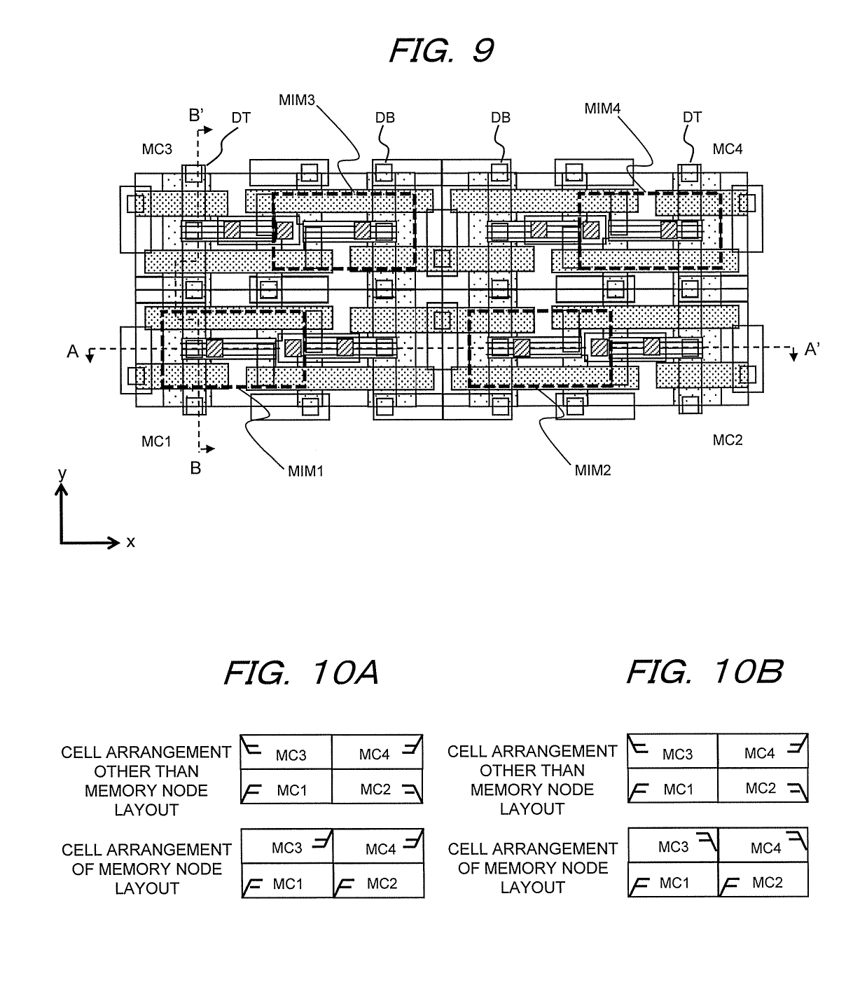

SRAM in the second embodiment and its memory cell are explained using FIG. 9 to FIG. 11. FIG. 9 is a conceptual diagram of a 2×2 cell array layout of the SRAM memory cell. FIG. 10A and FIG. 10B are schematic diagrams conceptually showing a memory node layout and a cell arrangement other than the memory node layout, respectively. FIG. 10A schematically shows the cell layout of FIG. 9, and FIG. 10B shows a modification of FIG. 10A. Moreover, FIG. 11 shows the section A-A′ in FIG. 9.

Referring to FIG. 9, in the layout of the SRAM cell of this embodiment, the MIM (Metal Insulator Metal) capacitances MIM1 to MIM4 that are the capacitances Cn are provided between respective memory nodes of the memory cells MC1 to MC4. Incidentally, as shown in FIG. 9, the MIM capacitances provided in the memory cells MC disposed between the same bit lines DT, DB are laid out in a staggered form so as not to be arranged being shifted to one of the bit line DT side and DB side similarly with the cell layout of FIG. 4. That is, while the MIM1 provided in the memory cell MC1 is disposed to be closer to the bit line DT side than to the middle of the bit line DT and the bit line DB, the MIM3 provided in the memory cell MC3 is disposed to be closer to the bit line DB side than to the middle of the bit line DT and the bit line DB. A reason for arranging the MIM1 to the MIM4 in a staggered form is the same as that of FIG. 4.

FIG. 10A schematically shows an arrangement of the MIM capacitances in FIG. 9. The MIM capacitances provided in each memory cell of the memory cells MC1 to MC4 are arranged as follows: the cell arrangement other than the memory node layout is a line symmetry arrangement (point symmetry arrangement) with a cell center located in an origin; and cell arrangement of the memory node layout is a parallel translation arrangement (slide arrangement), as shown in FIG. 10A. Incidentally, the cell arrangement of the memory node layout may be a mirror symmetry, as shown in FIG. 10B.

As shown in FIG. 11, the MIM capacitances provided in the memory cells MC1, MC2 are formed over the node NDT, and are electrically connected with the node NDT through the contacts CT2. The MIM capacitances MIM1, MIM2 are formed with a three-layer lamination structure so that the lower electrode LEL and the upper electrode UEL may face each other with the capacitance insulation film CF sandwiched thereby. This is what is called a stack-type MIM capacitor. For these lower electrode LEL and upper electrode UEL, a titanium nitride (TiN) film, a titanium (Ti) film, a tantalum (Ta) film, etc. are used, for example. Moreover, for the capacitance insulation film CF, a silicon nitride (Si₃N₄) film, a tantalum oxide (Ta₂O₅) film, a zirconium oxide (ZrO₂) film, etc. are used, for example.

In FIG. 11, the MIM capacitances except for the MIM1 and the MIM2 are arranged line-symmetrical with respect to an axis Y-Y′ and the MIM capacitances Cn (MIM1, MIM2) are in the parallel translation arrangement (slide arrangement).

As shown in FIG. 11, by forming the MIM capacitance Cn provided between the node NDT and the node NDB in a stack type, it is possible to reduce a risk that adjacent upper electrode UEL and lower electrode LEL may contact each other even in a case where the upper electrode UEL and the lower electrode LEL are enlarged; and therefore, a larger MIM capacitance Cn can be added therebetween.

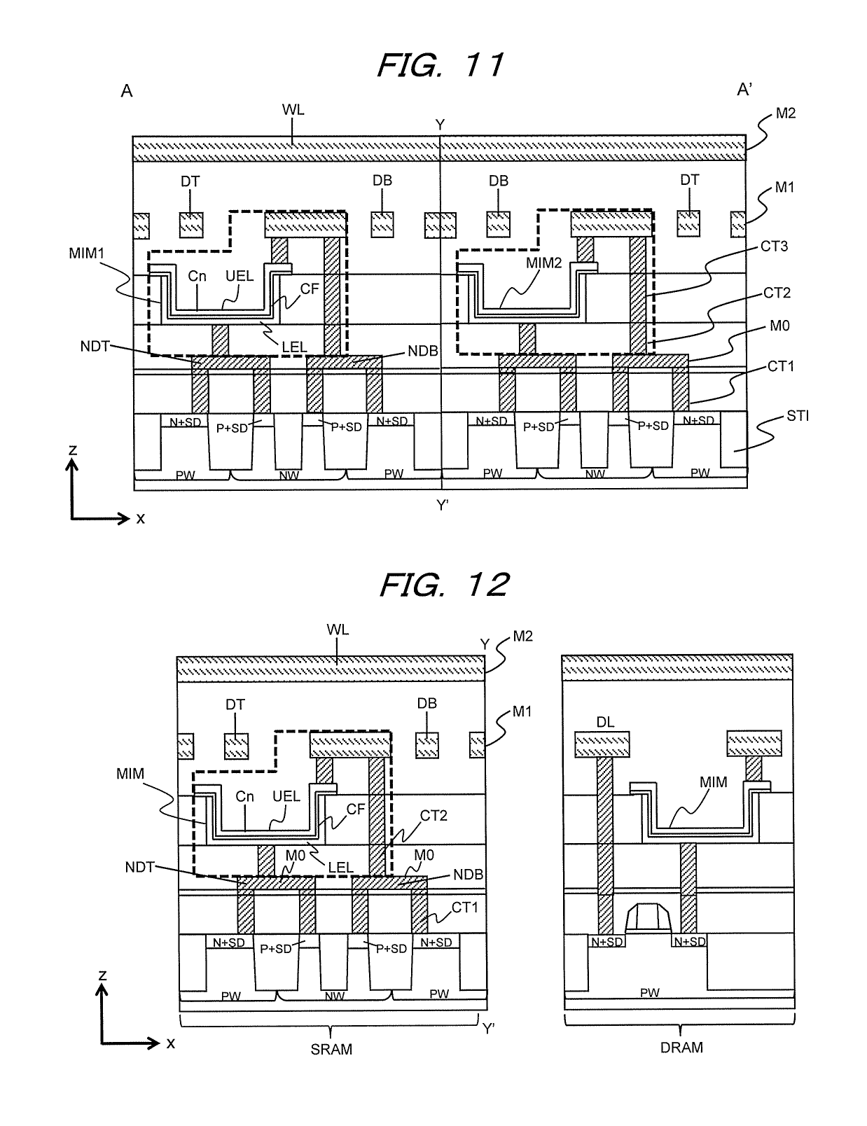

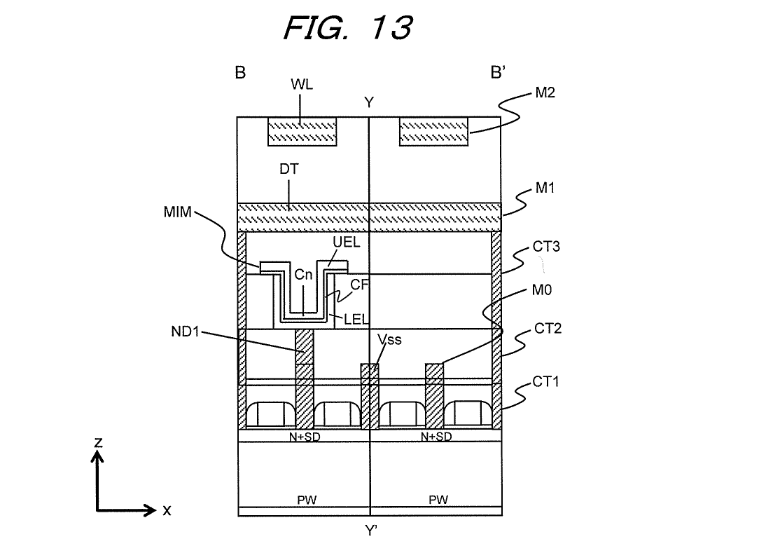

FIG. 12 shows an example of a DRAM-mixed-mounted product (eDRAM) in which the SRAM cell with the node capacitance Cn provided between the node NDT and the node NDB explained above and a DRAM cell are mixedly mounted. The MIM capacitance of the SRAM cell and the MIM capacitance of the DRAM cell are formed by the same process. That is, the MIM capacitance of the SRAM cell and the MIM capacitance of the DRAM cell are formed with the same material in the same layer. Incidentally, a section B-B′ in FIG. 9 is shown in FIG. 13 so that its cell structure may become clearer and is explained together.

As shown in FIG. 12, when the SRAM cell of this embodiment is mounted together with the DRAM, an MIM capacitor of the mixed-mounted DRAM (eDRAM) can be diverted for the MIM capacitance Cn of the SRAM cell. Moreover, the node NDT and the node NDB are formed with metal wiring M0. The lower electrode LEL of the MIM is connected to the node NDT by the contact CT2. The upper electrode UEL is connected to the node NDB through the metal wiring M1 etc. This forms the inter-node capacitance Cn with one element.

While the memory cell part as far as the metal wiring M0 is in a point symmetry arrangement, the MIM part becomes in the line symmetry arrangement. Thereby, even in a case where the upper electrode UEL and the lower electrode LEL are enlarged, a risk that the upper electrode UEL and the lower electrode LEL being located adjacent to it will contact each other can be reduced, and there is a merit that a larger MIM capacitance can be added.

Incidentally, only one MIM capacitance is connected between the node NDT and the node NDB by configuring the layout of one cell to be an asymmetrical cell. It becomes possible to increase the MIM electrostatic capacity compared with the conventional SRAM cell where two capacitances are serially connected. Note that, if the symmetry of MIM arrangement positions in the SRAM cell is impaired, the line capacitance will become imbalanced, either one of the bit line capacitances will increase, and the peak cell rate Cb·Vb/Iread characteristic will become worse. Therefore, in this embodiment, regularity is maintained by a 2×2 cell array.

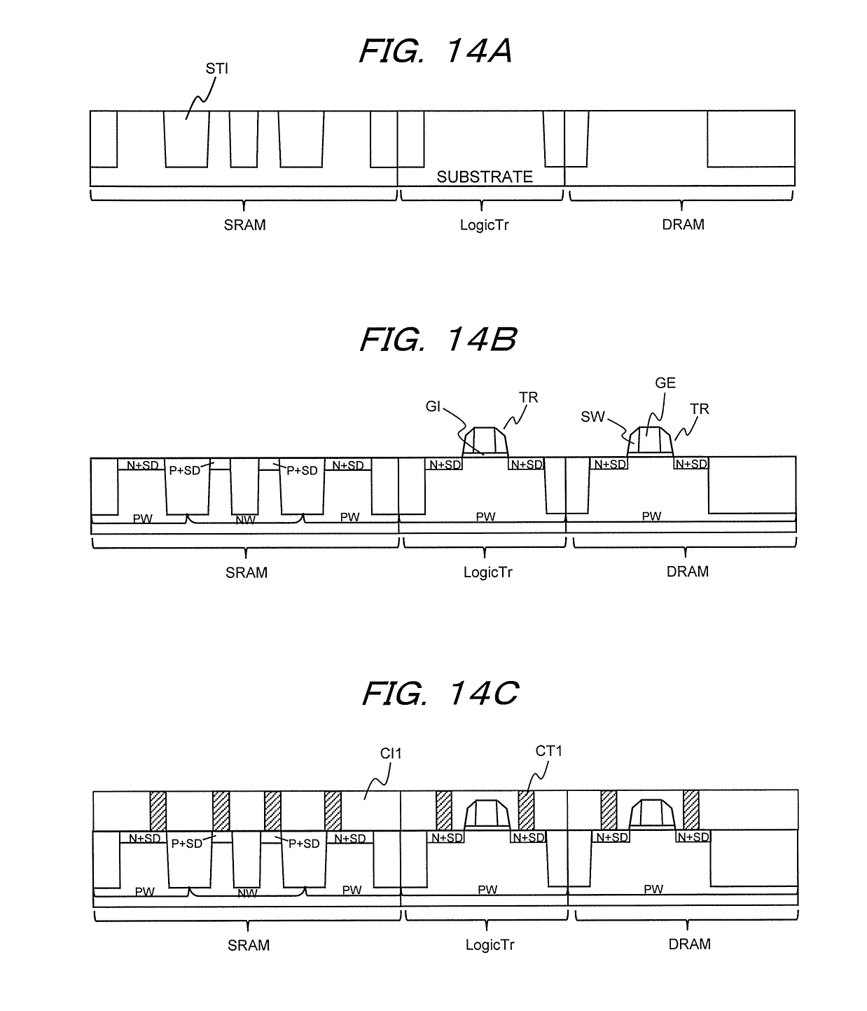

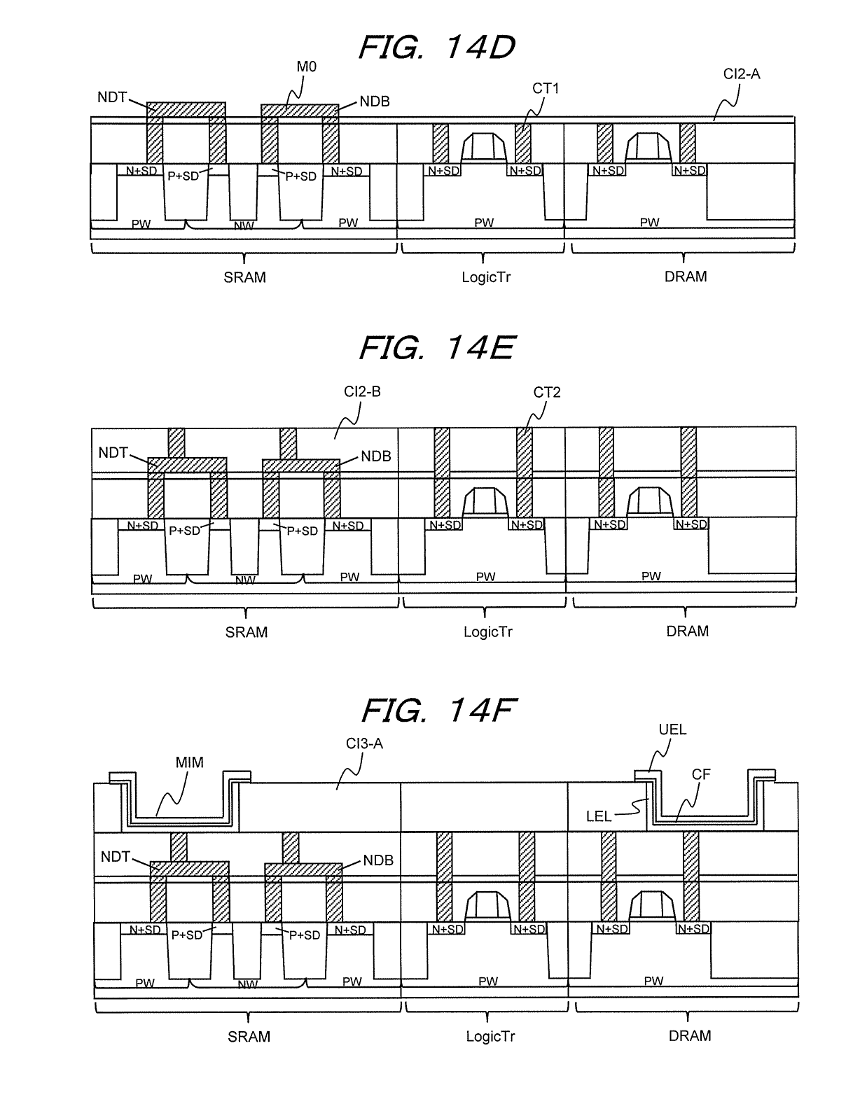

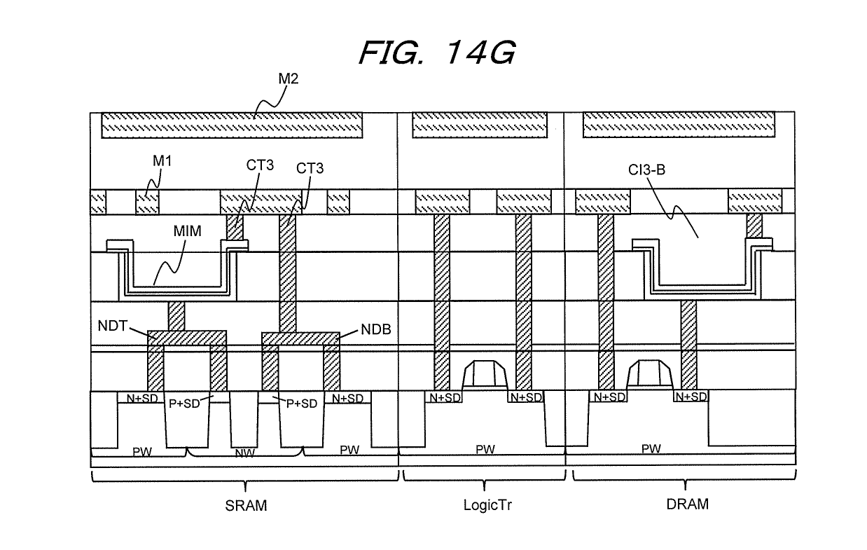

A method for manufacturing a structure of this embodiment shown in FIG. 9 to FIG. 13 is explained step by step using FIG. 14A to FIG. 14G. For intelligible explanation, it is explained using a sectional view in which three elements of the SRAM cell, the logic transistor (Logic Tr), and the DRAM cell are aligned. Incidentally, about the SRAM cell, the sectional view is taken along a direction that will show both nodes, the node NDT and the node NDB, like FIG. 11 and FIG. 12.

First, as shown in FIG. 14A, an element isolation layer STI is formed on a principal plane of a substrate such as a silicon wafer to effect separation with adjacent elements. (FIG. 14A)

Next, ion implantation for wells is performed, and subsequently a gate insulating film GI is formed on the substrate surface by gate oxidization. A gate electrode GE made of materials such as polysilicon is formed on the gate insulating film GI, and sidewall SW formation and ion implantation to the source region and the drain region are performed. A heat treatment required for activating injected impurities is performed, a silicide formation process is given using nickel (Ni) and cobalt (Co) in a desired site if needed, and a transistor TR is formed. (FIG. 14B)

Subsequently, an inter-contact layer film CI1 is formed on the substrate so as to cover the transistor TR, an opening is provided in a predetermined position, and contacts CT1 to a source electrode, a drain electrode, a gate electrode, etc. are formed. Incidentally, in FIG. 14C, the contact CT1 connected to the gate electrode is omitted. (FIG. 14C)

Furthermore, an inter-contact layer film CI2-A is formed. Subsequently, an opening for establishing a connection with the contact CT1 is formed in the inter-contact layer film CI2-A. The metal wiring M0 is formed by forming an electrode material such as tungsten and by dry etching it. The metal wiring M0 plays roles of two nodes (NDT, NDB) in the SRAM cell. (FIG. 14D)

Subsequently, an inter-contact layer film CI2-B is formed, and subsequently the contact CT2 is formed. (FIG. 14E)

Subsequently, an inter-contact layer film CI3-A is formed, and an opening for forming the MIM capacitance is formed. The lower electrode LEL made of titanium nitride (TiN) etc., the capacitance insulation film CF made of silicon nitride (Si₃N₄), tantalum oxide (Ta₂O₅), etc., and the upper electrode UEL made of titanium nitride (TiN), etc. are formed, and these are processed by dry etching to form an MIM capacitance. Thereby, the node NDT of the SRAM and the lower electrode LEL of the MIM are connected. (FIG. 14F)

After this, an inter-contact layer film CI3-B is formed, and the contact CT3 is formed. Subsequently, first layer wiring (interconnection) (metal wiring M1) made of copper (Cu) etc. is formed. Thereby, the node NDB is connected to the upper electrode UEL through the contact CT3 and the metal wiring M1, and accordingly, a capacitance comprised of a single element can be formed between the node NDT and the node NDB. Finally, a top layer wiring layer including second layer wiring (metal wiring M2) is formed to complete a semiconductor chip.

### Third Embodiment

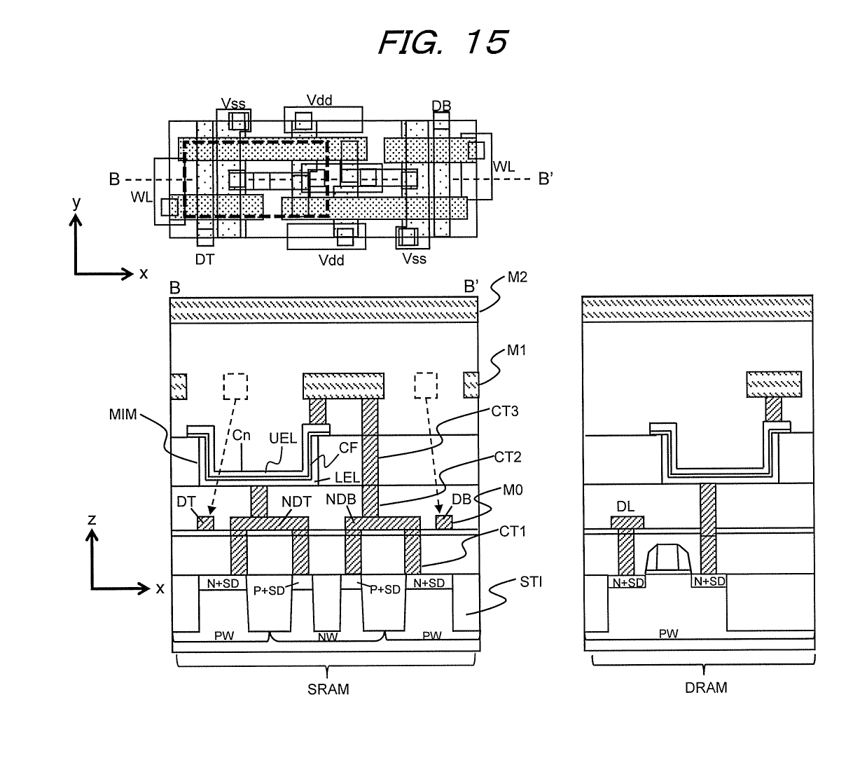

SRAM in a third embodiment and its memory cell are explained using FIG. 15. A section of the SRAM in FIG. 15 is the section B-B′ of the cell layout in FIG. 15. Comparing and referring to FIG. 12, the SRAM cell of this embodiment is different from the SRAM of FIG. 12 in a respect that the SRAM cell of this embodiment has the bit lines DT, DB that are formed with a lowermost layer metal wiring layer (layer of the metal wiring M0), not with a first layer metal wiring layer (layer of the metal wiring M1).

By changing (dropping) a layer of the bit lines DT, DB from the layer of the metal wiring M1 to the layer of the metal wiring M0, the bit line capacitance Cb further decreases. Since the smaller the ratio (Cb/Cn ratio) of the bit line capacity Cb and the inter-node capacitance Cn, the more the DNM (dynamic noise margin) is improved, this alteration can improve the stability of the SRAM cell further.

Incidentally, also in FIG. 15, the cell layout (cell arrangement) is the same as that of FIG. 9. That is, when the memory cells have been disposed in an array form, the MIMs are laid out in a staggered form. Moreover, in FIG. 15, also in the DRAM cell, a bit line DL is formed in the layer of the metal wiring M0.

Moreover, FIG. 15 shows the example in which both of the bit lines DT, DB are changed from the layer of the metal wiring M1 to the layer of the metal wiring M0. In this configuration, by changing at least either of the bit lines DT, DB onto the layer of the metal wiring layer M0, the DNM (dynamic noise margin) can be improved, although a decrement amount of the bit line capacity Cb is reduced. That is, by forming at least either of the bit lines DT, DB in a layer higher than the inter-node capacitance Cn (MIM) and forming the other of them in a layer lower than the inter-node capacitance Cn (MIM), the DNM (dynamic noise margin) is improved.

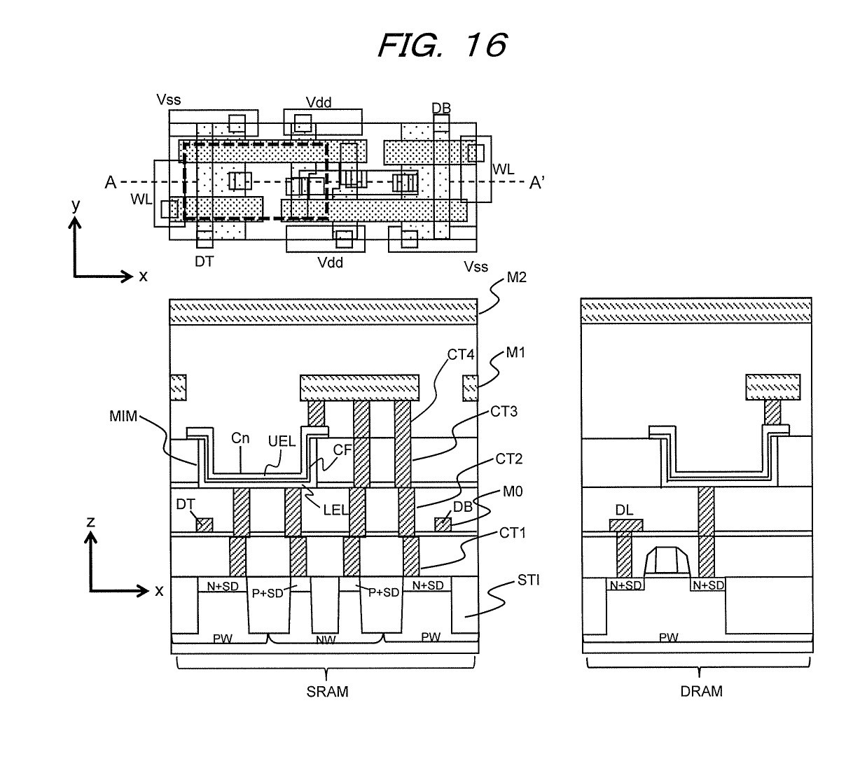

FIG. 16 shows a modification of FIG. 15. In the SRAM cell of FIG. 15, nodes of the driver transistor DR1 and the load transistor LD1 and nodes of the driver transistor DR2 and the load transistor LD2 are connected with the metal wiring M0, respectively, and nodes by this connection are designated as the node NDT and the node NDB, respectively, which are electrically connected with the MIM through the contacts CT2, CT3.

In contrast to this, the SRAM cell of FIG. 16 is different from the SRAM of FIG. 15 in a respect that terminals of the transistors DR, LD are raised (extended) to the layer of the metal wiring M1 through the contacts CT1, CT2, CT3, and CT4, and are connected with the metal wiring M1 without establishing node connection of the driver transistor DR and load transistor LD with the metal wiring M0.

That is, the upper electrode UEL of the MIM that constitutes the inter-node capacitance Cn is electrically connected with an element of the SRAM cell on the substrate through the multiple contacts CT1, CT2, CT3, and CT4 that are laid over multiple layers and the metal wiring M1. Moreover, the lower electrode LEL of the MIM that constitutes the inter-node capacitance Cn is electrically connected with an element of the SRAM cell on the substrate through the multiple contacts CT1, CT2 laid over multiple layers.

Adopting the configuration as shown in FIG. 16 makes available the semiconductor device according to the present invention by designing the bit lines in the layer of the metal wiring M0 as priority when an area for wiring of connecting the nodes becomes scant.

Incidentally, also in FIG. 16, a cell layout (cell arrangement) is the same as that of FIG. 9. That is, when the memory cells have been arranged in an array form, the MIMs are laid out in a staggered form. Moreover, also in the DRAM cell, the bit line DL is formed in the layer of the metal wiring M0.

In the above, although the invention made by the present inventors was concretely explained based on the embodiments, it goes without saying that the present invention is not limited to the embodiments and can be altered variously within a range that does not deviate from the gist of the invention.

### LIST OF REFERENCE SIGNS

AC1, AC2—Access transistor,
CF—Capacitance insulation film,
CI1, CI2-A, CI2-B, CI3-A, CI3B—Inter-contact layer film,
Cn—Node capacitance,
CT1 to CT4—Contact,
DR1, DR2—Driver transistor,
DT, DT1, DTn, DB, DB1, DBn, DL—Bit line (digit line),
GE—Gate electrode,
GI—Gate insulating film,
LD1, LD2—Load transistor,
LEL—Lower electrode,
MC, MC1 to MC4—Memory cell,
MIM, MIM1 to MIM5—MIM capacitance,
M0 to M2—Metal wiring,
ND, NDT, NDB—Node,
STI—Element isolation layer,
SW—Sidewall,
TR—Transistor,
UEL—Upper electrode,
WL—Word line.

What is claimed is:

1. A semiconductor device comprising:
a first SRAM cell with a first capacitive element provided between a first node connected to a first bit line and a second node connected to a second bit line; and
a second SRAM cell with a second capacitive element provided between a third node connected to the first bit line and a fourth node connected to the second bit line,
wherein the first capacitive element is disposed to be closer to the first bit line side than to a middle point of the first bit line and the second bit line, and the second capacitive element is disposed to be closer to the second bit line side than to the middle point of the first bit line and the second bit line.

2. The semiconductor device according to claim 1,
wherein the first capacitive element is disposed planarly overlapping the first bit line and the second capacitive element is disposed planarly overlapping the second bit line.

3. The semiconductor device according to claim 1,
wherein the first bit line and the second bit line make up a single pair of bit lines in a memory cell array and the first capacitive elements and the second capacitive elements are provided in the same number between the pair of bit lines.

4. The semiconductor device according to claim 1,
wherein the first SRAM cell and the second SRAM cell are disposed adjacent to each other.

5. The semiconductor device according to claim 1,
wherein the first capacitive element is disposed apart from the second bit line and the second capacitive element is disposed apart from the first bit line.

6. The semiconductor device according to claim 1,
wherein the first capacitive element is configured with a three-layer structure of an upper electrode, a capacitance insulation film, and a lower electrode, and the upper electrode is disposed planarly overlapping the first bit line and apart from the second bit line.

7. The semiconductor device according to claim 1,
wherein the first capacitive element is configured with a three-layer structure of an upper electrode, a capacitance insulation film, and a lower electrode, and the lower electrode is disposed planarly overlapping the first bit line and apart from the second bit line.

8. The semiconductor device according to claim 3,
wherein in the memory cell array, a capacitive element of another SRAM cell connected to a common word line is disposed to be closer to the same side to which the capacitive element of the first SRAM cell or the second SRAM cell connected to the word line is disposed.

9. The semiconductor device according to claim 1,
wherein at least either of the first bit line and the second bit line is disposed in a layer higher than the first capacitive element and the second capacitive element.

10. The semiconductor device according to claim 1,
wherein at least either of the first bit line and the second bit line is disposed in a layer lower than the first capacitive element and the second capacitive element.

11. The semiconductor device according to claim 10,
wherein the first capacitive element and the second capacitive element are each configured with a three-layer structure of an upper electrode, a capacitance insulation film, and a lower electrode, and the each upper electrode is electrically connected with a transistor of the first SRAM cell and a transistor of the second SRAM cell by a plurality of contacts that are laid over a plurality of layers.

12. The semiconductor device according to claim 11,
wherein the each lower electrode is electrically connected with the transistor of the first SRAM cell and the transistor of the second SRAM cell by the contacts that are laid over the layers.

13. The semiconductor device according to claim 1,
wherein the semiconductor device is a DRAM-mixed-mounted semiconductor device in which a DRAM cell is mounted, and the first capacitive element and the second capacitive element are formed with the same material on the same layer as that of a capacitor of the DRAM cell.

14. A method for manufacturing a semiconductor device comprising the steps of:
(a) forming an element that constitutes an SRAM cell in an SRAM formation area of a principal plane of a semiconductor wafer and forming an element that constitutes a DRAM cell in a DRAM formation area of the principal plane of the semiconductor wafer;
(b) forming a first inter-layer insulation film that covers the element constituting the SRAM cell and the element constituting the DRAM cell on these elements;
(c) forming two pieces of wiring that electrically connect with an element constituting the SRAM cell on the first inter-layer insulation film in the SRAM formation area and serve as two memory nodes of the SRAM;
(d) forming a second inter-layer insulation film in the SRAM formation area and the DRAM formation area that covers the two pieces of wiring; and
(e) forming a three-layer lamination film of a first conductive film serving as a lower electrode of an MIM, an insulating layer serving as a capacitance insulation film of the MIM, and a second conductive film serving as an upper electrode of the MIM on the second inter-layer insulation film, and forming the MIM in each of the SRAM formation area and the DRAM formation area by dry etching,
wherein the MIM in the SRAM area is such that the lower electrode of the MIM is electrically connected with one of the two pieces of wiring and the upper electrode of the MIM is electrically connected with the other of the two pieces of wiring.

15. The method for manufacturing a semiconductor device according to claim 14,
wherein the first conductive film and the second conductive film are one of a titanium nitride film, a titanium film, or a tantalum film.

16. The method for manufacturing a semiconductor device according to claim 14,
wherein the insulation layer is one of a silicon nitride film, a tantalum oxide film, or a zirconium oxide film.
